(19) United States
(12) Patent Application Publication
(10) Pub. No.: US 2023/0345780 A1
(43) Pub. Date: Oct. 26, 2023

(54) ELECTRO-OPTICAL DEVICE AND IMAGE DISPLAY DEVICE

(71) Applicant: SEIKO EPSON CORPORATION, Tokyo (JP)

(72) Inventor: Takehiko KUBOTA, Matsumoto-shi (JP)

(73) Assignee: SEIKO EPSON CORPORATION, Tokyo (JP)

(21) Appl. No.: 18/306,210

(22) Filed: Apr. 24, 2023

(30) Foreign Application Priority Data
Apr. 25, 2022 (JP) 2022-071830

(51) Int. Cl. H10K 59/131; G02B 27/01; G03B 21/20

(52) U.S. Cl. CPC H10K 59/131; G02B 27/0172; G03B 21/204; G02B 2027/0178

(57) ABSTRACT

An electro-optical device includes a light-emitting element including a first electrode, a light-emitting layer, and a second electrode, a driving transistor provided corresponding to the light-emitting element, a relay electrode electrically coupled to a gate electrode of the driving transistor and provided at a layer between the gate electrode and the first electrode of the light-emitting element, a power supply line provided at the same layer as that of the relay electrode, extending in a first direction in plan view, and electrically coupled to the first electrode of the light-emitting element, and a conductive member provided between the relay electrode and the power supply line in plan view and supplied with a constant potential.

The present application is based on, and claims priority from JP Application Serial Number 2022-071830, filed Apr. 25, 2022, the disclosure of which is hereby incorporated by reference herein in its entirety.

### BACKGROUND

### 1. Technical Field

The present disclosure relates to an electro-optical device and an image display device.

### 2. Related Art

In recent years, an organic electro-luminescence (EL) panel (electro-optical device) that displays an image using an organic light-emitting diode (OLED) has been developed, and application of the organic EL panel to image display devices including a head-mounted display and a projector has been studied. The organic EL panel includes an image generation region, and a plurality of pixel circuits corresponding to a plurality of pixels for generating an image is provided in a matrix in the image generation region. In addition, a plurality of scanning lines for driving the plurality of pixel circuits and a plurality of data lines orthogonal to the scanning lines are provided in the image generation region, and the pixel circuit is formed in an intersection region of the scanning line and the data line.

For example, JP-A-2013-213979 discloses an electro-optical device including a relay node (relay electrode) electrically coupled to a gate electrode of a driving transistor of a pixel circuit, and a power supply line (power supply wiring) provided in a circuit on an anode side of an OLED (light-emitting element).

In the electro-optical device disclosed in JP-A-2013-213979 described above, as miniaturization of a panel progresses, an interval between the relay node electrically coupled to the gate electrode of the transistor of the pixel circuit and the power supply line on the anode side of the OLED becomes narrow, and a parasitic capacitor is generated between the relay node and the power supply line. In such a situation, when a potential to the gate of the transistor, that is, a potential of the relay node changes due to switching of a level of a control signal supplied to the pixel circuit, a current value flowing through electric wiring changes due to influence of the parasitic capacitor between the relay node and the power supply line, which causes crosstalk. As a result, there was a possibility that flicker is conspicuous in an image output from the electro-optical device.

### SUMMARY

In order to solve the above-described problem, an electro-optical device according to one aspect of the present disclosure includes a light-emitting element including a first electrode, a light-emitting layer, and a second electrode, a driving transistor provided corresponding to the light-emitting element, a relay electrode electrically connected to a gate electrode of the driving transistor and provided at a layer between the gate electrode and the first electrode of the light-emitting element, a power supply line provided at the same layer as that of the relay electrode, extending in a first direction in plan view, and electrically connected to the first electrode of the light-emitting element, and a conductive member provided between the relay electrode and the power supply line in plan view and supplied with a constant potential.

### BRIEF DESCRIPTION OF THE DRAWINGS

FIG. 1 is a perspective view illustrating a configuration of an electro-optical device of a first exemplary embodiment.

FIG. 2 is a schematic diagram illustrating a configuration of the electro-optical device of FIG. 1.

FIG. 3 is an equivalent circuit diagram of a pixel circuit included in each pixel of the electro-optical device of FIG. 1.

FIG. 4 is a cross-sectional view illustrating a basic configuration of the pixel circuit of the electro-optical device of FIG. 1.

FIG. 5 is a plan view of the pixel circuit of the electro-optical device of FIG. 1.

FIG. 6 is a plan view of the pixel circuit of FIG. 5.

FIG. 7 is a cross-sectional view of the pixel circuit of FIG. 5.

FIG. 8 is a schematic diagram illustrating a configuration of an optical device provided with the electro-optical device of FIG. 1.

FIG. 9 is a schematic diagram illustrating a configuration of an image display device provided with the electro-optical device of FIG. 1.

FIG. 10 is a perspective view illustrating a configuration of an optical system of the image display device illustrated in FIG. 9.

FIG. 11 is an optical path diagram of the optical system illustrated in FIG. 10.

FIG. 12 is a schematic diagram for explaining a layout of a pixel circuit of an electro-optical device of a second exemplary embodiment.

FIG. 13 is a schematic diagram for explaining a layout of a pixel circuit of an electro-optical device of a third exemplary embodiment.

FIG. 14 is a schematic diagram for explaining the layout of the pixel circuit of the electro-optical device of FIG. 13.

FIG. 15 is a schematic diagram for explaining the layout of the pixel circuit of the electro-optical device of FIG. 13.

FIG. 16 is a cross-sectional view of the pixel circuit of the electro-optical device of FIG. 13.

FIG. 17 is a schematic diagram for explaining a layout of a pixel circuit of an electro-optical device of a modified example of the third exemplary embodiment.

FIG. 18 is a schematic diagram for explaining the layout of the pixel circuit of the electro-optical device of FIG. 17.

FIG. 19 is a cross-sectional view of the pixel circuit of the electro-optical device of FIG. 17.

FIG. 20 is a cross-sectional view of the pixel circuit of the electro-optical device of FIG. 17.

FIG. 21 is a schematic diagram illustrating a configuration of another image display device provided with the electro-optical device of FIG. 1.

### DESCRIPTION OF EXEMPLARY EMBODIMENTS

### First Exemplary Embodiment

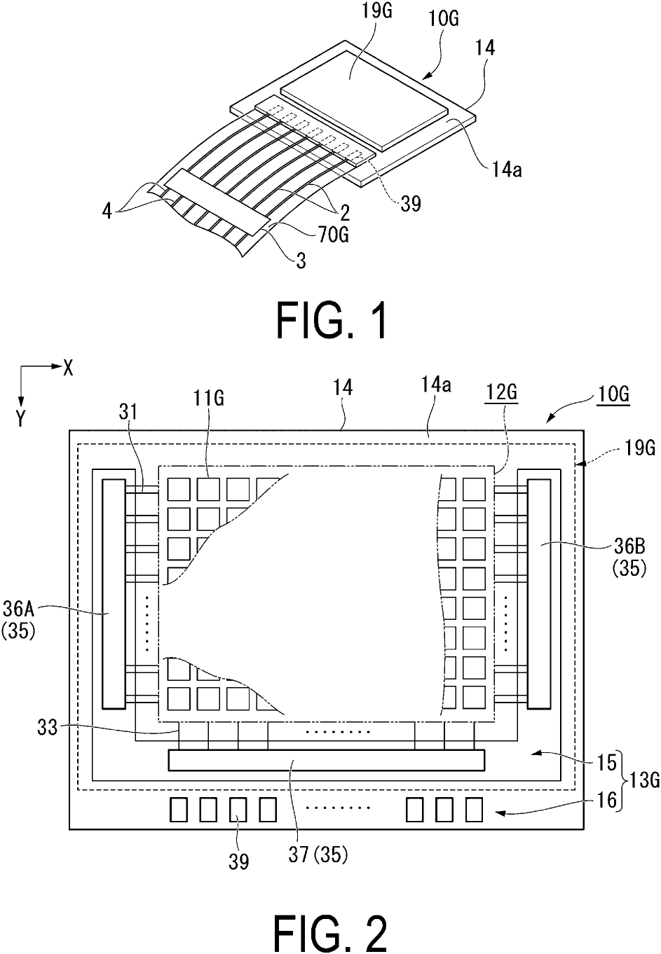

A first exemplary embodiment of the present disclosure will be described below using FIGS. 1 to 11. In each of the figures below, in order to make each component easier to see, a scale of dimensions may be changed depending on the component.

### Electro-Optical Device

FIG. 1 is a perspective view illustrating a configuration of an electro-optical device 10G of the first exemplary embodiment. The electro-optical device 10G is a device in which, for example, an OLED is used as a light-emitting element 54G to be described later. As illustrated in FIG. 1, the electro-optical device 10G includes a substrate 14, a pixel generation unit 19G, and a plurality of mounting terminals 39. The pixel generation unit 19G and the plurality of mounting terminals 39 are provided at a front surface 14a of the substrate 14. The plurality of mounting terminals 39 is disposed spaced apart from each other along one side of a rectangular region occupied by the pixel generation unit 19G. One connector portion of a flexible flat cable 70G is coupled to the plurality of mounting terminals 39. Another connector portion of the flexible flat cable 70G is coupled to a control substrate (not illustrated).

The flexible flat cable 70G is provided with a plurality of wiring lines 2, 4, and a control circuit 3. One end of each of the plurality of wiring lines 2 is coupled to a respective one of the plurality of mounting terminals 39. The other end of each of the plurality of wiring lines 2 is coupled to the control circuit 3. As will be described later, the control circuit 3 generates an image signal indicating a potential corresponding to brightness of the light-emitting element 54G, and supplies the image signal to the mounting terminal 39 via the plurality of wiring lines 2. One end of each of the plurality of wiring lines 4 is coupled to the control circuit 3. The other end of each of the plurality of wiring lines 4 is coupled to an upper circuit (not illustrated).

FIG. 2 is a plan view illustrating the configuration of the electro-optical device 10G. In FIG. 2, a horizontal direction of the front surface 14a of the substrate 14 of the electro-optical device 10G is defined as an X direction, and a vertical direction orthogonal to the X direction of the front surface 14a is defined as a Y direction. As illustrated in FIG. 2, the pixel generation unit 19G is provided at the front surface 14a of the substrate 14. The front surface 14a includes a pixel region 12G and a non-pixel region 13G. In the pixel region 12G, a plurality of pixels 11G is disposed in a matrix along the X direction and the Y direction, and the pixel region 12G is a rectangular region when viewed from a direction orthogonal to the X direction and the Y direction. A plurality of scanning lines 31 extending in parallel with the X direction, and a plurality of data lines 33 extending in parallel with the Y direction are provided in the pixel region 12G. The pixel 11G is formed corresponding to each of regions where the plurality of scanning lines 31 and the plurality of data lines 33 intersect. A pixel circuit included in the pixel 11G will be described later.

The non-pixel region 13G includes a peripheral region 15 and a mounting region 16. The peripheral region 15 is a rectangular frame-shaped region surrounding the pixel region 12G when viewed from the direction orthogonal to the X direction and the Y direction. A driving circuit 35 that drives the plurality of pixels 11G is provided in the peripheral region 15. The driving circuit 35 includes a scanning line driving circuits 36A, 36B, and a data line driving circuit 37. Since the driving circuit 35 is formed at the front surface 14a of the substrate 14 in the electro-optical device 10G as described above, the electro-optical device 10G is a circuit built-in type device constituted by an active element including a transistor.

The mounting region 16 is a region provided on a side opposite to the pixel region 12G in the Y direction with respect to the data line driving circuit 37 provided in the peripheral region 15, that is, a region provided outside the peripheral region 15. The plurality of mounting terminals 39 is provided in the mounting region 16. A video signal and a power supply voltage necessary for at least driving the plurality of pixels 11G of the electro-optical device 10G are input to the mounting terminal 39.

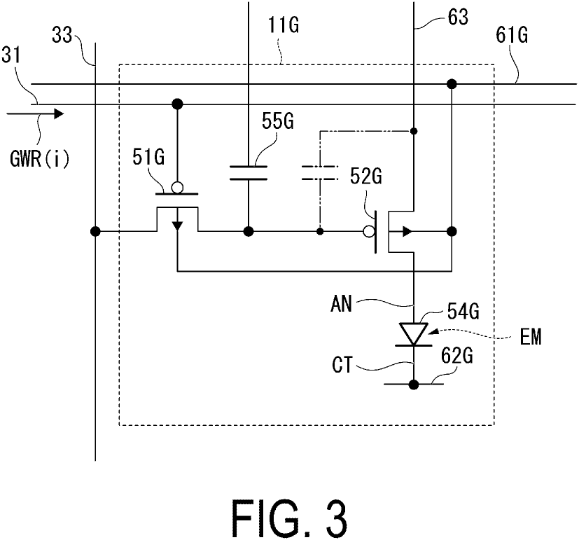

FIG. 3 is an equivalent circuit diagram of the pixel circuit included in the pixel 11G. Since configurations of the pixel circuits included in the plurality of pixels 11G are common to each other, the pixel circuit included in the pixel 11G in an i-th row and a j-th column will be described here as an example. i represents a number of a row in which the pixel 11G is disposed, and is an integer from 1 to m. j represents a number of a column in which the pixel 11G is disposed, and is an integer from 1 to n. The pixel circuit of the pixel 11G includes a selection transistor 51G, a driving transistor 52G, a light-emitting element 54G, and a retention capacitor 55G. Each of the selection transistor 51G and the driving transistor 52G is, for example, a P-channel type metal-oxide-semiconductor field-effect transistor (MOS-FET).

A gate electrode of the selection transistor 51G is electrically coupled to the scanning line 31 in the i-th row. One region of source/drain regions of the selection transistor 51G is electrically coupled to the data line 33 in the j-th column. Another region of the source/drain regions of the selection transistor 51G is electrically coupled to a gate electrode of the driving transistor 52G, and one electrode of the retention capacitor 55G. A back gate of the selection transistor 51G is electrically coupled to a power supply line 61G to which a power supply potential is applied.

The gate electrode of the driving transistor 52G is electrically coupled to the above other region of the source/drain regions of the selection transistor 51G, and the one electrode of the retention capacitor 55G. One region of source/drain regions of the driving transistor 52G is electrically coupled to a power supply line 63 different from the power supply line 61G. Another region of the source/drain regions of the driving transistor 52G is electrically coupled to one electrode of the light-emitting element 54G, that is, an anode AN. A back gate of the driving transistor 52G is electrically coupled to the power supply line 61G.

The light-emitting element 54G is a light-emitting element that emits green light. A light-emitting layer EM of the light-emitting element 54G is sandwiched between the anode and another electrode of the light-emitting element 54G, that is, a cathode CT, and is, for example, an OLED or a micro-LED (µLED). The one electrode of the light-emitting element 54G is electrically coupled to the above other region of the source/drain regions of the driving transistor 52G. The other electrode of the light-emitting element 54G is electrically coupled to a power supply line 62G to which the power supply potential is applied.

The retention capacitor 55G is a capacitor for retaining a voltage between the gate electrode of the driving transistor 52G, and the above one region of the source/drain regions of the driving transistor 52G. The one electrode of the retention capacitor 55G is electrically coupled to the above other region of the source/drain regions of the selection transistor 51G, and the gate electrode of the driving transistor 52G. Another electrode of the retention capacitor 55G is electrically coupled to a power supply line (not illustrated) different from the power supply line 61G. Note that, as the retention capacitor 55G, a capacitor which is parasitic on the gate electrode of the driving transistor 52G may be used, and a capacitor formed by sandwiching an insulating layer between mutually different conductive layers at a silicon substrate may be used.

In the pixel circuit of the pixel 11G configured as described above, when a scanning signal GWR(i) supplied to the scanning line 31 in the i-th row is at a high (H) level, the selection transistor 51G is in an OFF-state. On the other hand, when the scanning signal GWR(i) is at a low (L) level, the selection transistor 51G is in an ON-state. When the selection transistor 51G is in the ON-state, a current flows through the retention capacitor 55G in accordance with a potential difference Vd1 between a potential of the data line 33 and a potential of the other electrode of the retention capacitor 55G, so that the retention capacitor 55G is charged until a voltage between the electrodes of the retention capacitor 55G reaches the potential difference Vd1.

When a gate potential of the driving transistor 52G exceeds a threshold voltage of the driving transistor 52G, a drive current flows from the power supply line 63 to the power supply line 62G, via the driving transistor 52G and the light-emitting element 54G. A value of the drive current is controlled by the gate potential of the driving transistor 52G. A voltage between the gate electrode of the driving transistor 52G and the above one region of the source/drain regions of the driving transistor 52G electrically coupled to the power supply line 63 is equal to the voltage held by the retention capacitor 55G, that is, the voltage between the electrodes of the retention capacitor 55G. Therefore, the drive current has a current value corresponding to the voltage held by the retention capacitor 55G. Further, when the drive current flows through the light-emitting element 54G, the light-emitting element 54G emits green light having intensity corresponding to the drive current.

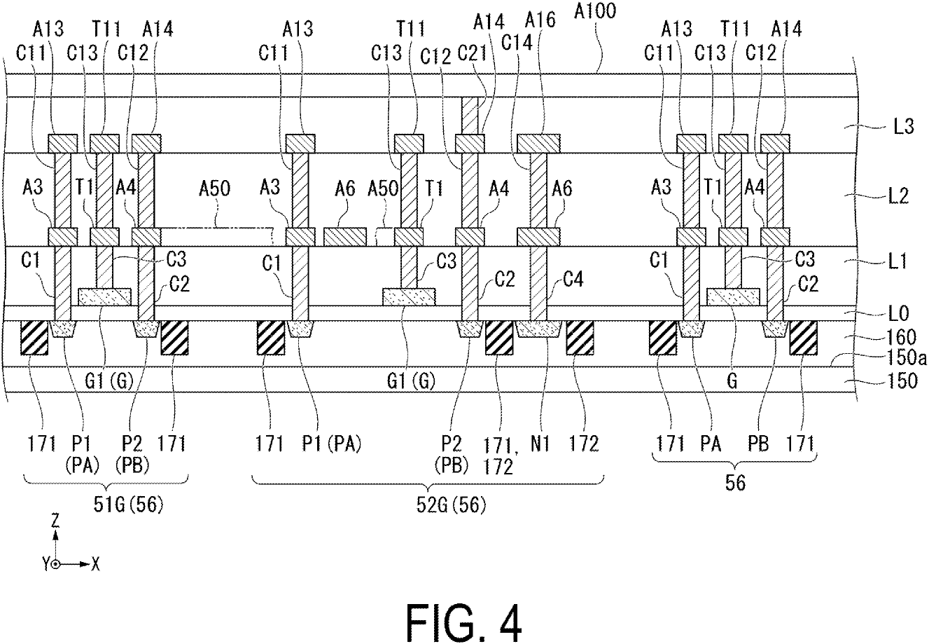

FIG. 4 is a cross-sectional view illustrating a basic configuration of a bottom of the pixel circuit illustrated in FIG. 3. In each of FIG. 4 and subsequent figures, a direction orthogonal to the X direction and the Y direction, parallel to a thickness direction of the pixel circuit, and opposite to a vertical direction is defined as a Z direction. A plan view in the description with reference to FIG. 4 and a plan view in the claims to be described later mean observation along a direction orthogonal to the X direction and the Y direction, that is, the Z direction, and a front surface 150a is observed from above a semiconductor substrate 150 along a direction orthogonal to the front surface 150a of the semiconductor substrate 150. Hereinafter, a front side surface in the Z direction of each component will be referred to as a front surface, and a rear side surface in the Z direction of each component will be referred to as a bottom surface.

As illustrated in FIG. 4, each component of the pixel circuit included in the pixel 11G is formed above the P-type semiconductor substrate 150 formed of a Si substrate, that is, forward in the Z direction from the front surface 150a of the semiconductor substrate 150. In an upper region including the front surface 150a in the semiconductor substrate 150, that is, in a front region in the Z direction in the semiconductor substrate 150, an N-type well 160 is formed over the entire front surface 150a. An N-type impurity dopant is injected into the N-type well 160 at appropriate density. Appropriate density of each type of impurity dopant means density at which electrical characteristics and desired effects of a region containing the impurity dopant can be stably maintained with respect to the semiconductor substrate 150, when characteristics of the semiconductor substrate 150 are taken into consideration.

A plurality of P-type diffusion regions Pj and one or more N-type diffusion regions Nk are formed in an upper region of the N-type well 160 including the front surface 150a of the substrate 150 for the pixel circuit of the one pixel 11G. Each of j and k is an optional natural number. Regarding the pixel circuit of the pixel 11G, in the basic structure illustrated in FIG. 4, for example, six P-type diffusion regions P1 to P6 and one N-type diffusion region N1 are formed at the N-type well 160. The P-type diffusion region Pj is formed by injecting a P-type impurity dopant at appropriate density into the front surface 150a of a predetermined region of the N-type well 160. That is, the P-type diffusion region Pj contains the P-type impurity dopant. The N-type diffusion region Nk is formed by injecting an N-type impurity dopant at appropriate density into the front surface 150a of a predetermined region different from the region where the P-type diffusion region Pj is formed at the N-type well 160 in plan view. That is, the N-type diffusion region Nk contains the N-type impurity dopant more than the surrounding N-type well 160.

The P-type diffusion region Pj acts as a source region or a drain region of a transistor 56 including the selection transistor 51G and the driving transistor 52G. At the N-type well 160, a shallow trench isolation (STI) 171 is provided in a frame shape in plan view surrounding P-type diffusion regions PA and PB used for one transistor 56. By providing the STI 171, a leakage current between the transistors 56 adjacent to each other in plan view is reduced, and a withstand pressure is secured.

The transistor 56 includes at least a gate electrode layer G, and the P-type diffusion regions PA and PB, and is a P-channel type MOS-FET. The P-type diffusion region PA acts as one region of the source/drain regions of the transistor 56. The P-type diffusion region PB acts as another region of the source/drain regions of the transistor 56.

In the transistor 56, the driving transistor 52G includes a gate electrode layer G1, the P-type diffusion regions P1 and P2, and the N-type diffusion region N1. The P-type diffusion region P1 acts as one region of the source/drain regions of the driving transistor 52G. The P-type diffusion region P2 acts as the other region of the source/drain regions of the driving transistor 52G. The N-type diffusion region N1 acts as a body power supply of the transistor 56.

At the N-type well 160, an STI 172 is provided in a frame shape in plan view surrounding the N-type diffusion region N1 used for the driving transistor 52G. In FIG. 4, of the STI 171 surrounding the P-type diffusion regions PA and PB in plan view, the STI 171 disposed with the P-type diffusion regions PA and PB interposed therebetween in the X direction is illustrated, and of the STI 172 surrounding the N-type diffusion region N1 in plan view, the STI 172 disposed with the N-type diffusion region N1 interposed therebetween in the X direction is illustrated. A part of the STI 172 is shared with the STI 171 surrounding the P-type diffusion regions P1 and P2.

A potential of the N-type diffusion region N1 of the driving transistor 52G is set to be equivalent to a potential of a high potential applied to the source region, and supplied.

A gate insulating layer L0 is formed at front surfaces of the N-type well 160, the P-type diffusion region Pj, and the N-type diffusion region Nk, that is, at the front surface 150a of the substrate 150. The gate insulating layer L0 is formed of, for example, silicon oxide (SiO₂). At a front surface of the gate insulating layer L0 between the P-type diffusion region PA or P1 and the P-type diffusion region PB or P2 in plan view, the gate electrode layer G of the transistor 56 or the gate electrode layer G1 of the driving transistor is formed by, for example, patterning. The gate electrode layer G or G1 is formed of, for example, polycrystalline silicon (poly-Si). An interlayer insulating layer L1 covering the gate electrode layer G or G1 and the gate insulating layer L0 is provided.

In at least a partial region of a region where each P-type diffusion region Pj is formed in plan view, a contact hole is formed which penetrates the interlayer insulating layer L1 and the gate insulating layer L0 in the Z direction from a front surface of the interlayer insulating layer L1 and reaches each P-type diffusion regions Pj. Additionally, in at least a partial region of a region where the gate electrode layer G or G1 is formed in plan view, a contact hole is formed which penetrates the interlayer insulating layer L1 in the Z direction from the front surface of the interlayer insulating layer L1 and reaches the gate electrode layer G or G1. Further, in at least a partial region of a region where each N-type diffusion region Nk is formed in plan view, a contact hole is formed which penetrates the interlayer insulating layer L1 and the gate insulating layer L0 in the Z direction from the front surface of the interlayer insulating layer L1 and reaches each N-type diffusion regions Nk.

A conductive material is embedded in the respective contact holes to form contact plugs C1 to C4. The above conductive material is, for example, tungsten (W). However, the above-described conductive material may be the same as a conductive material constituting the scanning line 31, the date line 33, the power supply line 61G, or each electrode layer, and the contact hole may be filled with the conductive material constituting the scanning line 31, the date line 33, or the power supply line 61G in a forming step of the transistors 56. One end of the contact plug C1, that is, an end on a rear side in the Z direction is electrically coupled to the P-type diffusion region PA or P1. One end of the contact plug C2 is electrically coupled to the P-type diffusion region PB or P2. One end of the contact plug C3 is electrically coupled to the gate electrode layer G or G1. One end of the contact plug C4 of the driving transistor 52G is electrically coupled to the N-type diffusion region N1. An end surface of the other end of each of the contact plugs C1 to C4 is flush with the front surface of the interlayer insulating layer L1.

In a predetermined region of the front surface of the interlayer insulating layer L1 including the above other end surface of the contact plug C1, an electrode layer A3 is formed by, for example, patterning. The electrode layer A3 is a member forming a part of an electrode layer constituting the one region of the source/drain regions of the transistor 56 on which the P-type diffusion region PA or P1 acts, or a member electrically coupled to an electrode layer constituting the above one region. In a predetermined region of the front surface of the interlayer insulating layer L1 including the above other end surface of the contact plug C2, an electrode layer A4 is formed by, for example, patterning. The electrode layer A4 is a member forming a part of an electrode layer constituting the other region of the source/drain regions of the transistor 56 on which the P-type diffusion region PB or P2 acts, or a member electrically coupled to an electrode layer constituting the above other region.

In a predetermined region of the front surface of the interlayer insulating layer L1 including the above other end surface of the contact plug C3, a relay layer T1 is formed by, for example, patterning. The relay layer T1 is a relay member (relay electrode) electrically coupled to the gate electrode layer G of each transistor 56. In a predetermined region of the front surface of the interlayer insulating layer L1 including the above other end surface of the contact plug C4 of the driving transistor 52G, an electrode layer A6 is formed by, for example, patterning. The electrode layer A6 is a member electrically coupled to the power supply line 61G of the transistor 56.

For example, in an image circuit illustrated in FIG. 3, it is assumed that the source region of the selection transistor 51G is electrically coupled to the column line 33 in the j-th column, and the drain region of the selection transistor 51G is electrically coupled to the gate electrode of the driving transistor 52G and the one electrode of the retention capacitor 55G. In addition, it is assumed that the drain region of the driving transistor 52G is electrically coupled to the anode AN of the light-emitting element 54G, and the source region of the driving transistor 52G is electrically coupled to the power supply line 63.

In the above assumption, it is assumed that the P-type diffusion region P1 of a basic configuration of the selection transistor 51G of an image circuit illustrated in FIG. 4 acts as a source region, and the P-type diffusion region P2 acts as a drain region. In this case, the electrode layer A3 and an electrode layer A13 electrically coupled to the selection transistor 51G are a part of a conductive layer constituting the data line 33, or are electrically coupled to the conductive layer constituting the data line 33, and for example, are electrically coupled to the conductive layer constituting the data line 33, by a conductive member (not illustrated) extending along a plane parallel to the X direction and the Y direction between the electrode layers A3 and A13, and the conductive layer constituting the data line 33, or a contact plug (not illustrated) extending along the Z direction. The electrode layer A4 and an electrode layer A14 may be electrically coupled to the relay layer T1 and a relay layer T11 as indicated by alternate long and short dash lines, and for example, may be electrically coupled to the relay layers T1 and T11 by a conductive member (not illustrated) extending along a plane parallel to the X direction and the Y direction between the electrode layers A4 and A14 and the relay layers T1 and T11 or a contact plug (not illustrated) extending along the Z direction. An electrode layer A50 formed of a conductive member between the electrode layers A4 and A14 and the relay layers T1 and T11 and a contact plug (not illustrated) are electrically coupled to a conductive layer constituting the one electrode of the retention capacitor 55G.

The relay layers T1 and T11 are a part of a conductive layer constituting the scanning line 31, or are electrically coupled to the conductive layer constituting the scanning line 31.

Further, on the assumption that the P-type diffusion region P1 of the basic configuration of the driving transistor 52G of the image circuit illustrated in FIG. 4 acts as the drain region, and the P-type diffusion region P2 acts as the source region as described above, the electrode layers A3 and A13 are a part of a conductive layer constituting the power supply line 63, or are electrically coupled to the conductive layer constituting the power supply line 63. The electrode layers A4 and A14 are electrically coupled to an electrode constituting the one electrode of the light-emitting element 54G, that is, the anode AN, and more particularly, are electrically coupled to an electrode layer A100 described later.

As described above, the relay layers T1 and T11 are electrically coupled to the electrode layers A4 and A14. The electrode layer A6 and an electrode layer A16 are a part of the conductive layer constituting the power supply line 63, or are electrically coupled to the conductive layer constituting the power supply line 63.

In the basic structure of the pixel circuit of the pixel 11G illustrated in FIG. 4, an interlayer insulating layer L2 covering the electrode layers A3, A4, and A6, the relay layer T1, and the interlayer insulating layer L1 is provided. At a front surface of the interlayer insulating layer L2, the electrode layer A13 electrically coupled to the electrode layer A3, the electrode layer A14 electrically coupled to the electrode layer A4, the electrode layer A16 electrically coupled to the electrode layer A6, and the relay layer T11 electrically coupled to the relay layer T1 are provided. For example, the electrode layers A3 and A13 are linked to each other by a contact plug C11. The contact plug C11 can be formed by embedding a conductive material in a contact hole formed in the interlayer insulating layer L2 and penetrating between the electrode layers A3 and A13. Similarly, the electrode layers A4 and A14 are linked by a contact plug C12. The contact plug C12 can be formed by embedding a conductive material in a contact hole formed in the interlayer insulating layer L2 and penetrating between the electrode layers A4 and A14. The relay layers T1 and T11 are linked to each other by a contact plug C13. The contact plug C13 can be formed by embedding a conductive material in a contact hole formed in the interlayer insulating layer L2 and penetrating between the relay layers T1 and T11. The electrode layers A6 and A16 of the driving transistor 52G are linked to each other by a contact plug C14. The contact plug C14 can be formed by embedding a conductive material in a contact hole formed in the interlayer insulating layer L2 and penetrating between the electrode layers A6 and A16.

In the basic structure of the pixel circuit of the pixel 11G illustrated in FIG. 4, an interlayer insulating layer L3 covering the electrode layers A13, A14, and A16, the relay layer T11, and the interlayer insulating layer L2 is provided. The electrode layer A100 electrically coupled to the electrode layer A14 is provided at a front surface of the interlayer insulating layer L3. A size of the electrode layer A100 in plan view corresponds to one pixel 11G. For example, the electrode layers A14 and A100 are linked to each other by a contact plug C21. The electrode layer A100 is an electrode layer constituting the one electrode of the light-emitting element 54G, that is, the anode AN, or is an electrode layer electrically coupled to the anode AN of the light-emitting element 54G.

Each of the electrode layers A3, A4, A6, A13, A14, A16 and the relay layers T1, T11 is made of metal including, for example, copper (Cu). Each of the interlayer insulating layers L1 to L3 is formed of, for example, SiO₂.

In the pixel circuit of the pixel 11G illustrated in FIG. 4, the electrode layer A100 is a component of an outermost layer. However, an interlayer insulating layer, an insulating layer, a semiconductor layer, and a conductive layer (not illustrated) may be provided at a layer upper than the electrode layer A100, that is, in front of the electrode layer A100 in the Z direction. The layered structure of the pixel circuit of the pixel 11G is appropriately designed in consideration of optical properties and electrical properties required for the electro-optical device 10G. For example, at least one or more components of the electrode layers A13, A16, the relay layer T11, the contact plugs C11, C13, and C14 may be omitted as appropriate.

In the pixel circuit of the pixel 11G of the electro-optical device 10G of the first exemplary embodiment, when the P-type diffusion region PB or P2 serves as the source region of the driving transistor 52G, the electrode layer A6 extends between the electrode layer A4 and the relay layer T1 in plan view of the front surface of the interlayer insulating layer L1. A layout of the respective components in the pixel circuit of the pixel 11G in plan view is appropriately designed in consideration of constraints on a shape and a size of the electro-optical device 10G in addition to the layered structure based on the above optical properties and electrical properties required for the electro-optical device 10G.

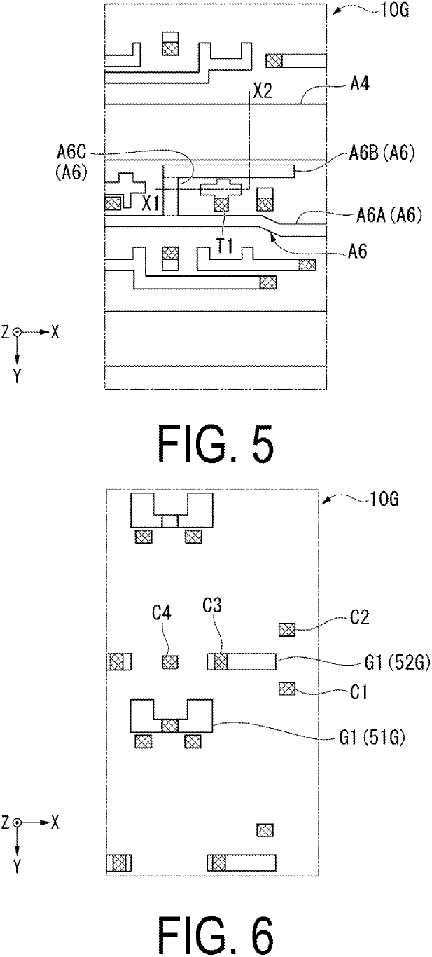

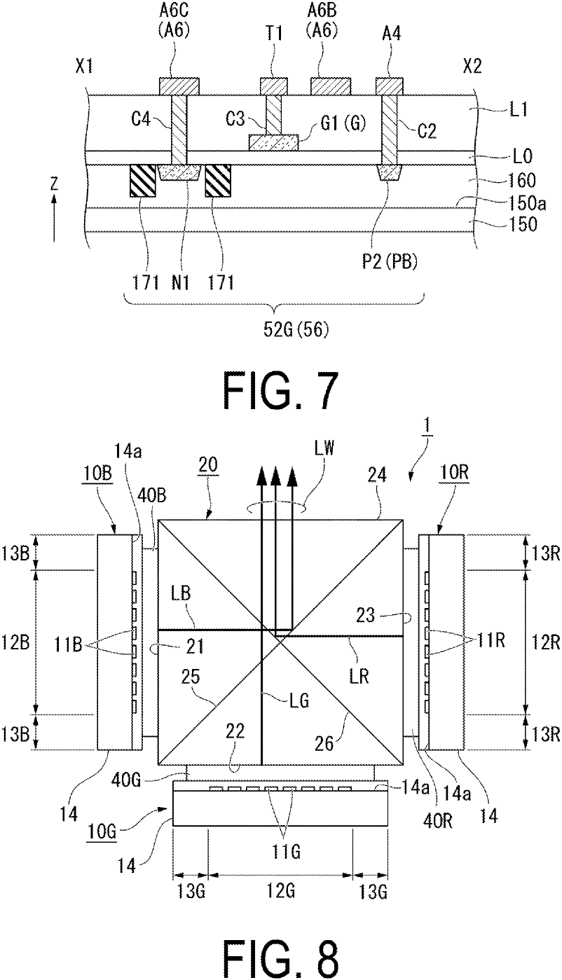

FIG. 5 is a schematic diagram illustrating a layout of an appropriately designed pixel circuit of the pixel 11G of the first exemplary embodiment in plan view at a front surface of the interlayer insulating layer L1. FIG. 6 is a schematic diagram illustrating a layout of the appropriately designed pixel circuit of the pixel 11G of the first exemplary embodiment in plan view at the front surface of the gate insulating layer L0. FIG. 7 is a diagram illustrating a configuration of the pixel circuit formed with the layout illustrated in FIGS. 5 and 6, and is a cross-sectional view when viewed from a line X1-X2 illustrated in FIG. 5. Note that, in FIG. 7, a configuration of a layer upper than the electrode layers A4, A6, and the relay layer T1, that is, a configuration in front of the electrode layers A4, A6, and the relay layer T1 in the Z direction is omitted.

The relay layer T1 illustrated in FIG. 5 is a conductive layer electrically coupled to the gate electrode layer G1 of the driving transistor 52G in the equivalent circuit diagram illustrated in FIG. 3. G1 (51G) illustrated in FIG. 6 represents the gate electrode layer G1 of the selection transistor 51G, and G1 (52G) in the same figure represents the gate electrode layer G1 of the driving transistor 52G. The contact plug C1 illustrated in FIG. 6 is formed in front of the relay layer T1 in the Y direction, and is electrically coupled to the anode AN (not illustrated). The contact plug C2 illustrated in FIG. 6 is electrically coupled to the electrode layer A4 formed at the back of the relay layer T1 in the Y direction as illustrated in FIG. 5. The contact plug C3 illustrated in FIG. 6 is electrically coupled to the relay layer T1 illustrated in FIG. 5. The contact plug C4 illustrated in FIG. 6 is electrically coupled to an electrode layer A6C, of the electrode layer A6 illustrated in FIG. 5. The electrode layer A6C links an electrode layer A6A to an electrode layer A6B formed at the back of the relay layer T1 in the Y direction and extending in the X direction, and extends in the Y direction.

As illustrated in FIGS. 5 and 7, in the pixel circuit of the pixel 11G of the electro-optical device 10G of the first exemplary embodiment, the electrode layer A6B is disposed between the electrode layer A4 and the relay layer T1 of the driving transistor 52G in the Y direction at the front surface of the gate insulating layer L0 in plan view and cross-sectional view. In this case, the electrode layer A4 is electrically coupled to the P-type diffusion region P2 or PB acting as the source region, and specifically is electrically coupled to the P-type diffusion region P2 or PB via the contact plug C2. The relay layer T1 is electrically coupled to the gate electrode layer G1 or G, and to be specific, is electrically coupled to the gate electrode layer G1 or G via the contact plug C3. In the pixel circuit of the pixel 11G of the electro-optical device 10G of the first exemplary embodiment, the electrode layers A6C and A6B are newly formed to extend from the electrode layer A6A at least required for the driving transistor 52G, that is, the electrode layer A6 electrically coupled to the N-type diffusion region N1 via the contact plug C4, so that the electrode layer A6B is provided between the electrode layer A4 and the relay layer T1 in the Y direction.

Since each of the electrode layers A6A, A6B, and A6C constituting the electrode layer A6 is electrically coupled to the N-type diffusion region N1 or Nk formed at the semiconductor substrate 150, resistance of each of the electrode layers A6A, A6B, and A6C is lower than that of the power supply line 61G, and a potential of each of the electrode layers A6A, A6B, and A6C is more stable than that of the power supply line 61G. As described above, since the electrode layer A4, the relay layer T1, and the electrode layer A6B therebetween are provided at layers identical to each other at the front surface of the interlayer insulating layer L1, an interval between the gate electrode layer G1 or G of the driving transistor 52G, and the power supply line 61G is stably shielded.

Next, a method of manufacturing the basic structure of the pixel circuit of the electro-optical device 10G of the first exemplary embodiment illustrated in FIGS. 4 to 7 will be briefly described. Although not illustrated, an ionized N-type impurity dopant is injected, for example, from a front side in the Z direction into a front side portion in the Z direction including a front surface of a P-type Si substrate constituting the semiconductor substrate 150 over the entire front surface 150a of the semiconductor substrate 150, to form the N-type well 160. Subsequently, an ionized P-type impurity dopant is injected from, for example, the front side in the Z direction into small regions that are different from each other, and are to be a source region or a drain region of the transistor 56, in a region of the N-type well 160 in plan view, thereby forming the P-type diffusion region Pj. Subsequently, an ionized N-type impurity dopant is injected from, for example, the front side in the Z direction into a small region which is different from the P-type diffusion region Pj, and is to be the power supply line 61G of the transistor 56, in a region of the N-type well 160 in plan view, thereby forming the N-type diffusion region Nk. Subsequently, a groove surrounding the P-type diffusion region Pj constituting the source region and the drain region is formed, by removing the N-type well 160 in a frame shape surrounding the P-type diffusion region Pj constituting the source region and the drain region in the region of the N-type well 160 in plan view. An insulating material that fills the groove and forms the STI 171 extending to the front side of the front surface side 150a of the substrate 150 in the Z direction is formed by, for example, a plasma chemical vapor deposition (CVD) method. Thereafter, an upper portion of a deposited layer made of the insulating material is removed by using, for example, a chemical mechanical polisher (CMP) apparatus until the front surface 150a of the semiconductor substrate 150, that is, a front surface of the N-type well 160 is exposed. For example, SiO₂ can be used as the insulating material.

Subsequently, the gate insulating layer L0 made of SiO₂ is formed at the front surface 150a of the semiconductor substrate 150 by, for example, a thermal oxidation method or a film forming method using a sputtering apparatus. Subsequently, an insulating material for constituting the interlayer insulating layer L1 is deposited with a thickness equivalent to that of the gate electrode layer G, at the front surface of the gate insulating layer L0 by, for example, a CVD method. As appropriate, a front surface of an insulating layer made of the insulating material is planarized. Subsequently, the insulating layer of a small region to be the gate electrode layer G in plan view is removed to form a hole. Inside the hole, for example, Poly-Si is grown as a material for forming the gate electrode layer G, to form the gate electrode layer G in the hole. As appropriate, a front surface of the gate electrode layer G may be planarized so as to be flush with the front surface of the surrounding insulating layer.

Subsequently, an insulating material is formed at the front surfaces of the gate electrode layer G and the surrounding insulating layer in plan view by, for example, an atomic layer deposition (ALD) method, to form the interlayer insulating layer L1. Thereafter, in regions overlapping the P-type diffusion region Pj and the N-type diffusion region Nk in plan view, respectively, at the interlayer insulating layer L1, contact holes penetrating through the interlayer insulating layer L1 and the gate insulating layer L0 to the respective front surfaces of the P-type diffusion region Pj and the N-type diffusion region Nk are formed, by patterning and reactive ion etching (RIE), for example. In addition, a contact hole penetrating the interlayer insulating layer L1 to the front surface of the gate electrode layer G is formed by, for example, patterning and a reactive ion etching (RIE) method in a region overlapping the gate electrode layer G in plan view at the interlayer insulating layer L1. Subsequently, a conductive material is embedded inside the respective contact holes to form contact plugs C1 to C4. As appropriate, front surfaces of the contact plugs C1 to C4 may be planarized so as to be flush with the front surface of the interlayer insulating layers L1.

Subsequently, a conductive material constituting each of the electrode layers A3, A4, A6 and the relay layer T1 is formed, at the front surfaces of the contact plugs C1 to C4 and the front surface of the interlayer insulating layer L1. Thereafter, by using patterning and an RIE method, of a conductive layer made of the conductive material, the conductive layers for respective regions to be the electrode layers A3, A4, A6 and the relay layer T1 in plan view are left, and by removing the conductive layer other than these regions, each of the electrode layers A3, A4, A6 and the relay layer T1 is formed at the front surface of the interlayer insulating layer L1. In a mask pattern for each of the electrode layers A3, A4, A6 and the relay layer T1 used in this step, a region of the electrode layer A6 is disposed between a region of the electrode layer A4 and a region of the relay layer T1 in plan view, that is, in a predetermined direction parallel to a front surface of a mask substrate. As illustrated in FIGS. 4 and 7, the predetermined direction indicates a direction in which the electrode layer A4 electrically coupled to the P-type diffusion region Pj acting as the source region of the transistor 56, and the relay layer T1 electrically coupled to the gate electrode layer G of the same transistor 56 are disposed spaced from each other. That is, when each of the electrode layers A3, A4, A6 and the relay layer T1 is formed at the front surface of the interlayer insulating layer L1, a mask having a pattern matching the layout illustrated in FIG. 5 in plan view is used.

Subsequently, the interlayer insulating layer L2 made of an insulating material is formed using, for example, an ALD method so as to cover each of the interlayer insulating layer L1, the electrode layers A3, A4, A6, and the relay layer T1. In respective regions overlapping the electrode layers A3, A4, A6, and the relay layer T1 in plan view at the interlayer insulating layer L2, contact holes penetrating the interlayer insulating layer L2 to the respective front surfaces of the electrode layers A3, A4, A6 and the relay layer T1 are formed by, for example, patterning and a reactive ion etching (RIE) method. Subsequently, a conductive material is embedded in the respective contact holes to form the contact plugs C11 to C14. As appropriate, front surfaces of the contact plugs C11 to C14 may be planarized so as to be flush with the front surface of the interlayer insulating layers L2.

Subsequently, a conductive material constituting each of the electrode layers A13, A14, A16 and the relay layer T11 is formed, at the front surfaces of the contact plugs C11 to C14 and the front surface of the interlayer insulating layer L2. Thereafter, by using patterning and an RIE method, of a conductive layer made of the conductive material, the conductive layers for respective regions to be the electrode layers A13, A14, A16 and the relay layer T11 in plan view are left, and by removing the conductive layer other than these regions, each of the electrode layers A13, A14, A16 and the relay layer T11 is formed at the front surface of the interlayer insulating layer L2.

Subsequently, the interlayer insulating layer L3 made of an insulating material is formed using, for example, an ALD method so as to cover each of the interlayer insulating layer L2, the electrode layers A13, A14, A16, and the relay layer T11. In a region of the interlayer insulating layer L3 overlapping the electrode layer A16 of the driving transistor 52G in plan view, a contact hole penetrating the interlayer insulating layer L3 to a front surface of the electrode layer A16 is formed by, for example, patterning and an RIE method. Subsequently, a conductive material is embedded in the contact hole to form the contact plug C21. As appropriate, a front surface of the contact plug C21 may be planarized so as to be flush with the front surface of the interlayer insulating layers L3. Subsequently, a conductive material constituting the electrode layer A100 is formed at the front surface of the contact plug C21 and the front surface of the interlayer insulating layer L3.

Through the above-described steps, the pixel circuit of the electro-optical device 10G of the first exemplary embodiment can be manufactured. Note that, as appropriate, these components may be stacked in the Z direction, at the front surface of the electrode layer A100, through steps similar to those for each of the interlayer insulating layer L2, the contact plugs C11 to C14, the electrodes layers A13, A14, A16, and the relay layer T11.

### Image Display Device

Next, an image display device provided with the electro-optical device 10G of the first exemplary embodiment will be described. FIG. 8 is a schematic diagram illustrating a configuration of an optical device 1 provided with the electro-optical device 10G of the first exemplary embodiment. As illustrated in FIG. 8, the optical device 1 includes the electro-optical device 10G, electro-optical devices 10B, 10R, and a dichroic prism 20. The electro-optical device 10G is a self-emission type electro-optical device that emits green image light LG to the dichroic prism 20. The electro-optical device 10B includes a configuration similar to that of the electro-optical device 10G described above, and is a self-emission type electro-optical device that emits blue image light LB to the dichroic prism 20. The electro-optical device 10R includes a configuration similar to that of the electro-optical device 10G, and is a self-emission type electro-optical device that emits red image light LR to the dichroic prism 20. Each of the electro-optical devices 10G, 10B, and 10R is an organic EL panel.

A wavelength region of a green color of the image light LG includes, for example, a wavelength region from 495 nm to 570 nm. The plurality of pixels 11G of the electro-optical device 10G emits green light. The image light LG emitted from the electro-optical device 10G is formed of green light emitted from each of the plurality of pixels 11G.

The front surface 14a of the substrate 14 of the electro-optical device 10G faces an incident surface 22 of green light of the dichroic prism 20, and is bonded to the incident surface 22 with a transmissive adhesive layer 40G interposed between the front surface 14a and the incident surface 22. In other words, the electro-optical device 10G is disposed such that the image light LG is vertically incident on the incident surface 22.

The electro-optical device 10B is a device in which an OLED or a µLED is used as a light-emitting element, and includes a pixel region 12B including a plurality of pixels 11B, and a non-pixel region 13B. A wavelength region of a blue color of the image light LB includes, for example, a wavelength region from 450 nm to 490 nm. The plurality of pixels 11B of the electro-optical device 10B emits blue light. The image light LB emitted from the electro-optical device 10B is formed of blue light emitted from each of the plurality of pixels 11B.

The front surface 14a of the substrate 14 of the electro-optical device 10B faces an incident surface 21 of blue light of the dichroic prism 20, and is bonded to the incident surface 21 with a transmissive adhesive layer 40B interposed between the front surface 14a and the incident surface 21. In other words, the electro-optical device 10B is disposed such that the image light LB is vertically incident on the incident surface 21.

The electro-optical device 10R is a device in which an OLED or a µLED is used as a light-emitting element, and includes a pixel region 12R including a plurality of pixels 11R, and a non-pixel region 13R. A wavelength region of a red color of the image light LR includes, for example, a wavelength region from 610 nm to 680 nm. The plurality of pixels 11R of the electro-optical device 10R emits red light. The image light LR emitted from the electro-optical device 10R is formed of red light emitted from each of the plurality of pixels 11R.

The front surface 14a of the substrate 14 of the electro-optical device 10R faces an incident surface 23 of red light of the dichroic prism 20, and is bonded to the incident surface 23 with a transmissive adhesive layer 40R interposed between the front surface 14a and the incident surface 23. In other words, the electro-optical device 10R is disposed such that the image light LR is vertically incident on the incident surface 23.

Each of the image light LG, image light LB, and image light LR is unpolarized light that does not have a polarization characteristic and does not have a specific vibration direction. Note that unpolarized light, namely, light that does not have a polarization characteristic is light that is not in a completely unpolarized state and includes a polarization component to some extent. For example, the light has a degree of polarization to the extent that does not actively affect an optical component including a dichroic mirror, for example, in terms of optical performance.

The dichroic prism 20 is constituted of a transmissive member having a quadrangular prism shape. In addition, the quadrangular prism-shaped transmissive member is configured by combining four triangular prism-shaped transmissive members. The dichroic prism 20 includes the incident surfaces 21, 22, 23 and an emission surface 24. The dichroic prism 20 further includes a first dichroic mirror 25 that does not have a polarization separation characteristic, and a second dichroic mirror 26 that does not have a polarization separation characteristic. The first dichroic mirror 25 and the second dichroic mirror 26 cross each other at an angle of 90°. The first dichroic mirror 25 reflects the image light LB incident through the incident surface 21 toward the emission surface 24, and transmits the image light LG incident through the incident surface 22 toward the emission surface 24. The second dichroic mirror 26 reflects the image light LR incident through the incident surface 23 toward the emission surface 24, and transmits the image light LG incident through the incident surface 22 toward the emission surface 24. Due to the characteristics of the first dichroic mirror 25 and the second dichroic mirror 26, synthesized image light LW generated by combining the image light LG, image light LB, and image light LR with each other is emitted from the emission surface 24.

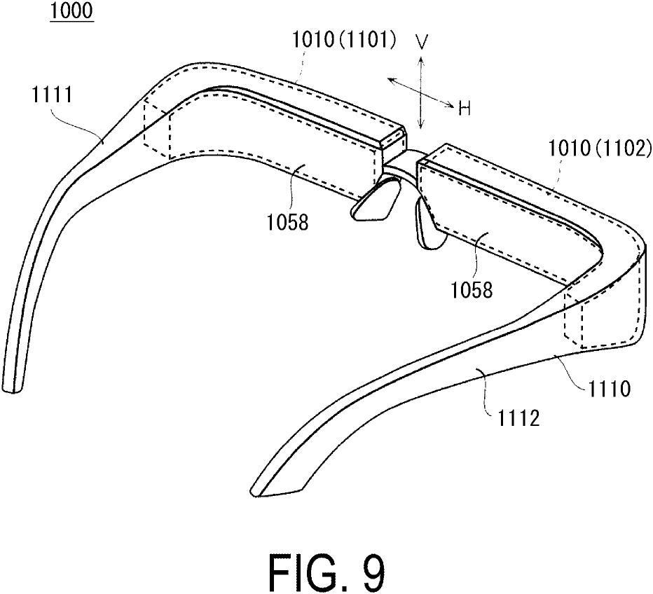

FIG. 9 is a schematic diagram illustrating a configuration of a head-mounted display (image display device) 1000 which is the image display device of the first exemplary embodiment. The head-mounted display 1000 is configured as a see-through eyeglass display, and includes a frame 1110 provided with left and right temples 1111 and 1112. Virtual image display units 1010 are supported by the frame 1110, and an image emitted from the virtual image display units 1010 is caused to be recognized as a virtual image by a user (not illustrated).

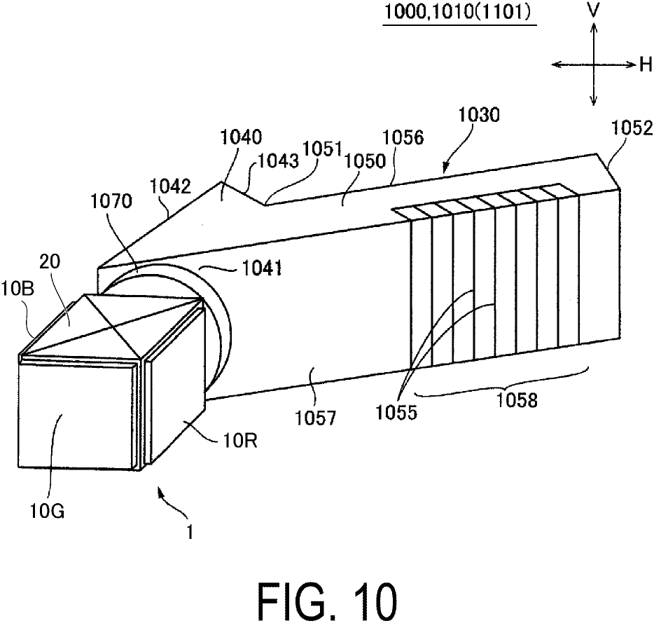

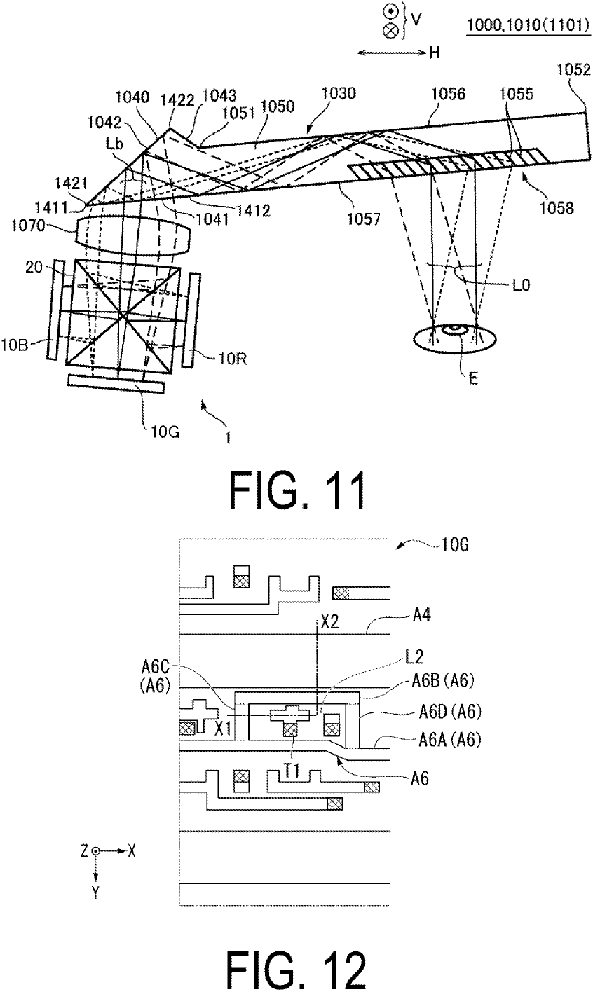

The head-mounted display 1000 is provided with a left-eye display unit 1101 and a right-eye display unit 1102 as the virtual display units 1010. The left-eye display unit 1101 and the right-eye display unit 1102 have the same configuration and are disposed left-right symmetrically. FIG. 10 is a perspective view illustrating a configuration of an optical system of the virtual image display unit 1010. FIG. 11 is a schematic diagram illustrating an optical path of the optical system illustrated in FIG. 10, and is a diagram when viewed from a direction orthogonal to a front surface of a light guiding portion 1050. As illustrated in FIGS. 10 and 11, the left-eye display unit 1101 includes the optical device 1, and a light guiding system 1030 that guides the synthesized image light LW emitted from the optical device 1 to an emitting portion 1058. A projection lens system 1070 is disposed between the optical device 1 and the light guiding system 1030. The synthesized image light LW emitted from the optical device 1 enters the light guiding system 1030 through the projection lens system 1070. The projection lens system 1070 is configured by a single collimate lens that has positive power.

The light guiding system 1030 includes a transmissive incidence portion 1040 from which the synthesized image light LW enters, and a transmissive light guiding portion 1050 having one end 1051 coupled to the incidence portion 1040. The incidence portion 1040 and the light guiding portion 1050 are configured by mutually integrated transmissive members.

A reflection film is not formed at the incident surface 1041, but the incident surface 1041 has optical transparency and optical reflectivity, and fully reflects light that is incident at an incident angle equal to or greater than a critical angle. A reflection surface 1042 is opposed to the incident surface 1041. One end 1422 of the reflection surface 1042 is farther away from the incident surface 1041 than another end 1421 of reflection surface 1042. That is, the incidence portion 1040 has a substantially triangular shape. The reflection surface 1042 is a flat surface, an aspherical surface, a free form surface, or the like. The reflection surface 1042 has a configuration in which a reflective metal layer made, mainly, of aluminum, silver, magnesium, chrome or the like, is formed.

The light guiding portion 1050 includes a first surface 1056 that extends from one end 1051 toward another end 1052, a second surface 1057 that faces the first surface 1056 in a parallel manner and extends from the end 1051 toward the end 1052, and an emitting portion 1058 provided at a portion of the second surface 1057 that is apart from the incidence portion 1040. The first surface 1056 and the reflection surface 1042 of the incidence portion 1040 are continuous with a sloped surface 1043 interposed therebetween. An interval between the first surface 1056 and the second surface 1057 is less than a thickness of the incidence portion 1040. The first surface 1056 and the second surface 1057 reflect all light that is incident at an incident angle equal to or greater than the critical angle, based on a refractive index difference between the light guiding portion 1050 and outside air. Thus, no reflection film is formed at the first surface 1056 and the second surface 1057.

The emitting portion 1058 is configured at a portion of the light guiding portion 1050 on the second surface 1057 side in the thickness direction. In the emitting portion 1058, a plurality of partial reflection surfaces 1055 that is sloped with respect to a direction orthogonal to the second surface 1057 is disposed mutually parallel to each other. The emitting portion 1058 is a portion of the second surface 1057 that overlaps with the plurality of partial reflection surfaces 1055, and has a predetermined width in an extending direction of the light guiding portion 1050. Each of the plurality of partial reflection surfaces 1055 is constituted of a dielectric multilayer film. In addition, at least one of the plurality of partial reflection surfaces 1055 may be a composite layer including a dielectric multilayer film and a reflective metal layer mainly containing one or more of aluminum, silver, magnesium, and chrome. When the partial reflection surface 1055 is configured to include a metal layer, it is possible to optimize an effect of enhancing reflectance of the partial reflection surface 1055, or incident angle dependence or polarization dependence of transmittance and the reflectance of the partial reflection surface 1055. Note that the emitting portion 1058 may include an optical element including a diffraction grating and a hologram.

In the head-mounted display 1000 provided with the above configuration, the synthesized image light LW formed of parallel light that enters from the incidence portion 1040 is refracted on the incident surface 1041 and propagates toward the reflection surface 1042. The synthesized image light LW is reflected on the reflection surface 1042, and propagates toward the incident surface 1041 again. At this time, since the synthesized image light LW is incident on the incident surface 1041 at the incident angle equal to or greater than the critical angle, the synthesized image light LW is reflected by the incident surface 1041 toward the light guiding portion 1050, and propagates toward the light guiding portion 1050. Note that, in the incidence portion 1040, the incident surface 1041 and the reflection surface 1042 may be formed of free form surfaces, and after the synthesized image light LW that is non-parallel light enters the incident surface 1041, the synthesized image light LW may be converted into parallel light while being reflected between the reflection surface 1042 and the incident surface 1041.

In the light guiding portion 1050, the synthesized image light LW is reflected, and advances between the first surface 1056 and the second surface 1057. A part of the synthesized image light LW that enters the partial reflection surface 1055 is reflected on the partial reflection surface 1055 and is emitted from the emitting portion 1058 toward an eye E of an observer. Further, at least a part of the rest of the synthesized image light LW incident on the partial reflection surface 1055 passes through the partial reflection surface 1055, and is incident on the next, adjacent, partial reflection surface 1055. Thus, the synthesized image light LW that is reflected on each of the plurality of partial reflection surfaces 1055 is emitted from the emitting portion 1058 toward the eye E of the observer. This enables the observer to recognize a virtual image. At this time, light entering the light guiding portion 1050 from an outside passes through the partial reflection surfaces 1055 after entering the light guiding portion 1050, and reaches the eye E of the observer. Thus, the observer can visually recognize a color image emitted from the optical device 1, and visually recognize a view of an outside in a so-called see-through manner.

The electro-optical device 10G of the first exemplary embodiment described above includes the light-emitting element 54G, the driving transistor 52G, the relay layer (relay electrode) T1, the electrodes layer A4, and the electrode layer (conductive member) A6. The light-emitting element 54G includes the anode (first electrode) AN, the light-emitting layer EM, and the cathode (second electrode). The driving transistor 52G is provided corresponding to the light-emitting element 54G. The relay layer T1 is electrically coupled to the gate electrode layer (gate electrode) G or G1 of the driving transistor 52G. The relay layer T1 is provided at the interlayer insulating layer (layer) L1 between the gate electrode layer G or G1 and the anode AN of the light-emitting element 54G, in the Z direction parallel to a thickness direction of the semiconductor substrate 150. The electrode layer A4 is provided at the same layer as that of the relay layer T1 and at the interlayer insulating layer T1, that is, at the same layer as that of the relay layer T1, extends in, for example, the X direction (first direction) in plan view of the electro-optical device 10G, and is electrically coupled to the electrode layer A100 (first electrode side) on the anode AN side of the light-emitting element 54G. The electrode layer A6 is provided between the relay layer T1 and the electrode layer A4 in plan view. A constant potential is supplied to the electrode layer A6.

In the configuration of the electro-optical device 10G of the first exemplary embodiment, if the electrode layer A6 or the electrode layer A6B is not interposed between the relay layer T1 and the electrode layer A4 at the front surface of the interlayer insulating layer L1, a parasitic capacitor indicated by a chain double-dashed line is generated between an input to the gate of the driving transistor 52G from a region of the source/drain regions of the selection transistor 51G electrically coupled to the retention capacitor 55G illustrated in FIG. 3, and an output from a region of the source/drain regions of the driving transistor 52G electrically coupled to the power supply line 63. A voltage change of the electrode layer A4 is transmitted to the relay layer T1 electrically coupled to the gate electrode G or G1 of the driving transistor 52G via the parasitic capacitor described above, and crosstalk or image flicker occurs. In the electro-optical device 10G of the first exemplary embodiment, resistance of each of the electrode layers A6 is lower than that of the power supply line 63, and a potential of each of the electrode layers A6 is more stable than that of the power supply line 63. According to the electro-optical device 10G of the first exemplary embodiment, since the electrode layer A6 is provided between the relay layer T1 and the electrode layer A4 in plan view, it is possible to satisfactorily shield between the relay layer T1 electrically coupled to the gate electrode layer G1 of the driving transistor 52G and the electrode layer A4, and to prevent the parasitic capacitor generated between the relay layer T1 and the electrode layer A4 in the existing electro-optical device from being generated. Therefore, it is possible to reduce crosstalk in the electro-optical device 10G of the first exemplary embodiment, and to suppress image flicker.

Further, the electro-optical device 10G of the first exemplary embodiment includes the P-type diffusion region (diffusion region) Pj containing the P-type impurity dopant and the N-type diffusion region (diffusion region) Nk containing the N-type impurity dopant in the N-type well 160 of the semiconductor substrate 150. That is, the plurality of diffusion regions including the P-type diffusion region Pj and the N-type diffusion region Nk is provided at the semiconductor substrate 150. The electrode layer (conductive member) A6 is electrically coupled to the N-type diffusion region N1 among the plurality of diffusion regions, and is electrically coupled to the N-type diffusion region N1 by, for example, the contact plug C4. According to the electro-optical device 10G of the first exemplary embodiment, since the electrode layer A6 is electrically coupled to the N-type diffusion region N1 having higher conductivity compared to the semiconductor substrate 150, it is possible to stabilize the potential of the electrode layer A6, and to enhance a shielding effect between the relay layer T1 and the electrode layer A4. Therefore, it is possible to reduce crosstalk in the electro-optical device 10G of the first exemplary embodiment, and to further suppress image flicker.

In addition, in the electro-optical device 10G of the first exemplary embodiment, since the light-emitting element 54G is, for example, an OLED (organic light-emitting diode), the electrode layer A6 can be used as a terminal electrically coupled to a body power supply.

In addition, the head-mounted display 1000 of the first exemplary embodiment includes the above-described electro-optical device 10G, the electro-optical devices 10B and 10R each having the similar configuration to that of the electro-optical device 10G, the optical device (optical system) 1 for displaying the image light LG, image light LB, and image light LR emitted from the electro-optical devices 10G, 10B, and 10R, respectively, the projection lens system (optical system) 1070, and the light guiding system (optical system) 1030. According to the head-mounted display 1000 of the first exemplary embodiment, it is possible to suppress crosstalk and flickering of an image to be observed displayed by the optical system that displays the image light LG, image light LB, and image light LR.

### Second Exemplary Embodiment

Next, a second exemplary embodiment of the present disclosure will be described below with reference to FIG. 12.

Note that, in each of exemplary embodiments after the second exemplary embodiment, a configuration common to that of the upper exemplary embodiment will be denoted by the same reference numerals as those of the configuration, and descriptions thereof will be omitted. In each of the exemplary embodiments after the second exemplary embodiment, configurations or contents different from those of the upper exemplary embodiment will be mainly described. In addition, an optical device and an image display device including an electro-optical device of each of the exemplary embodiments after the second exemplary embodiment are obtained by replacing the electro-optical devices 10G, 10B, and 10R in each of the optical device 1 and the head-mounted display 1000 described in the first exemplary embodiment with the electro-optical device of each of the exemplary embodiments.

A pixel circuit of the pixel 11G of the electro-optical device 10G of the second exemplary embodiment has a similar configuration to that of the pixel circuit of the pixel 11G of the first exemplary embodiment. FIG. 12 is a schematic diagram illustrating a layout in plan view at the front surface of the interlayer insulating layer L1 of the pixel circuit of the pixel 11G of the second exemplary embodiment. A layout in plan view at the front surface of the gate insulating layer L0 of the pixel circuit of the pixel 11G in the second exemplary embodiment, and a cross section taken along a line X1-X2 illustrated in FIG. 5 are similar to those in the first exemplary embodiment.

As illustrated in FIG. 12, in the pixel circuit of the pixel 11G of the electro-optical device 10G of the second exemplary embodiment, the electrode layer A6 includes an electrode layer A6D in addition to the electrode layers A6A, A6B, and A6C. The electrode layer A6D links another end of the electrode layer A6B opposite to one end electrically coupled to the electrode layer A6C in plan view to the electrode layer A6A, and extends along a V direction. That is, the relay layer T1 is disposed in a region surrounded by the electrode layer A6 including the electrode layers A6A to A6D. In addition, in the pixel circuit of the pixel 11G of the electro-optical device 10G of the second exemplary embodiment, similarly to the first exemplary embodiment, the electrode layer A4 is, similar to the relay layer T1, provided at the front surface of the interlayer insulating layer L1, and is provided at the same layer as that of the relay layer T1.

A method of manufacturing the electro-optical device 10G of the second exemplary embodiment is similar to the method of manufacturing the electro-optical device 10G of the first exemplary embodiment. However, when each of the electrode layers A3, A4, A6 and the relay layer T1 is formed at the front surface of the interlayer insulating layer L1, a mask having a pattern matching the layout illustrated in FIG. 12 in plan view is used.

The electro-optical device 10G of the second exemplary embodiment described above has a similar configuration to that of the electro-optical device 10G of the first exemplary embodiment, and thus has similar operational effects as those of the electro-optical device 10G of the first exemplary embodiment. In addition, in the electro-optical device 10G of the second exemplary embodiment, the relay layer (relay electrode) T1 is surrounded by the electrode layer (conductive member) A6 in plan view. The relay layer (relay electrode) T1 is disposed adjacent to the electrode layer (conductive member) A6 with the interlayer insulating layer (insulating layer) L2 interposed between the relay layer T1 and the electrode layer A6 in plan view, and surrounded by the electrode layer A6 with the interlayer insulating layer L2 interposed between the relay layer T1 and the electrode layer A6. According to the electro-optical device 10G of the second exemplary embodiment, it is possible to prevent occurrence of an unexpected parasitic capacitor in all directions around the relay layer T1 in plan view, and to enhance the shielding effect not only between the relay layer T1 and the electrode layer A4, but also for the relay layer T1. Therefore, it is possible to reduce crosstalk in the electro-optical device 10G of the first exemplary embodiment, and to further suppress image flicker.

### Third Exemplary Embodiment

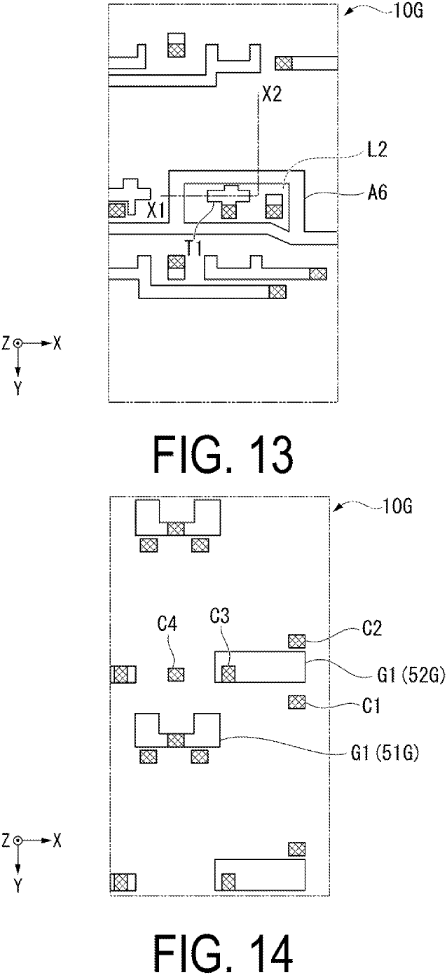

Next, a third exemplary embodiment of the present disclosure will be described below with reference to FIGS. 13 to 20.

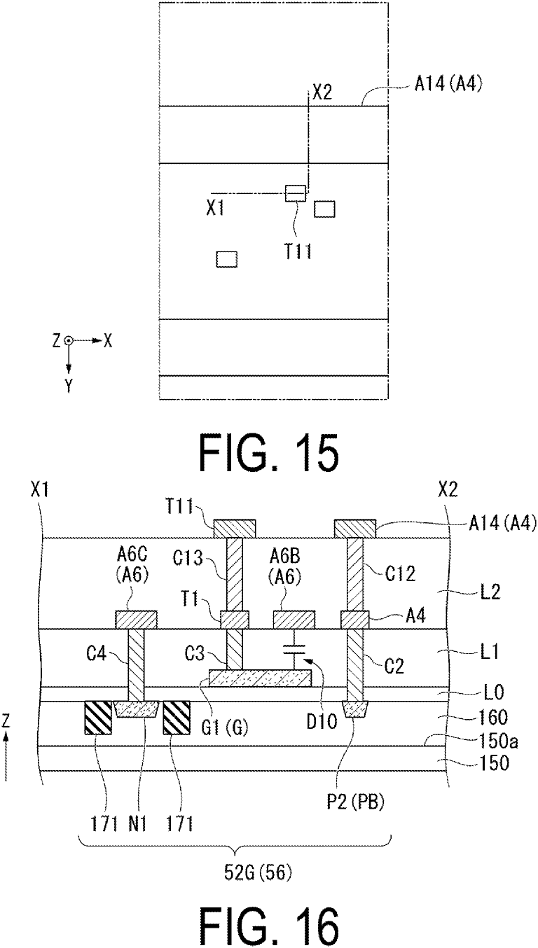

A pixel circuit of the pixel 11G of the electro-optical device 10G of the third exemplary embodiment has a similar configuration to that of the pixel circuit of the pixel 11G of the first exemplary embodiment. FIG. 13 is a schematic diagram illustrating a layout in plan view at the front surface of the interlayer insulating layer L1 of the pixel circuit of the pixel 11G of the third exemplary embodiment. FIG. 14 is a schematic diagram illustrating a layout in plan view at the front surface of the interlayer insulating layer L0 of the pixel circuit of the pixel 11G of the third exemplary embodiment. FIG. 15 is a schematic diagram illustrating a layout in plan view at the front surface of the interlayer insulating layer L2 of the pixel circuit of the pixel 11G of the third exemplary embodiment. FIG. 16 is a diagram illustrating a configuration of the pixel circuit formed with the layout illustrated in FIGS. 13 to 15, and is a cross-sectional view when viewed from a line X1-X2 illustrated in FIGS. 13 and 15. In FIG. 16, a configuration of an upper layer than the electrode layer A14, that is, a configuration of a front in the Z direction is omitted, but the electrode layer A14 is electrically coupled to the electrode layer A100 of the anode AN of the light-emitting element 54G.

As illustrated in FIGS. 13 to 16, in the pixel circuit of the pixel 11G of the electro-optical device 10G of the third exemplary embodiment, in the configuration and disposition described in the second exemplary embodiment, the uppermost electrode layer A14 is provided at the front surface of the interlayer insulating layer L2, for example, and is provided at a layer different from the relay layer T1. In addition, in the pixel circuit of the pixel 11G of the electro-optical device 10G of the third exemplary embodiment, at least a part of the electrode layer A6 of the driving transistor 52G overlaps the gate electrode layer G1 in plan view. To be more specific, an end portion of the gate electrode layer G1 closer to the electrode layer A4 extends in a direction closer to the electrode layer A4 than the relay layer T1 in plan view at the front surface of the gate insulation layer L0.

A method of manufacturing the electro-optical device 10G of the third exemplary embodiment is basically similar to the method of manufacturing the electro-optical device 10G of the first exemplary embodiment. However, when each of the electrode layers A3, A6 and the relay layer T1 is formed at the front surface of the interlayer insulating layer L1, a mask having a pattern matching the layout illustrated in FIG. 13 in plan view is used. The pattern of the electrode layer A6 in the mask used in forming each of the electrode layers A3, A6, and the relay layer T1 at the front surface of the interlayer insulating layer L1 overlaps at least a part of a region where a hole of the interlayer insulating layer L1 for forming the gate electrode layer G1 is formed in plan view.

The electro-optical device 10G of the third exemplary embodiment described above has a similar configuration to that of the electro-optical device 10G of the second exemplary embodiment, and thus has similar operational effects as those of the electro-optical device 10G of the second exemplary embodiment. As illustrated in FIG. 16, even when the electrode layer A14 and the relay layer T1 are not provided at layers identical to each other, the electrode layer A6 is provided between the electrode layer A14 and the relay layer T1 in plan view, so that the shielding effect between the electrode layer A14 and the relay layer T1 acts. In addition, the electro-optical device 10G of the third exemplary embodiment, at least a part of the electrode layer (conductive member) A6 overlaps the gate electrode layer (gate electrode) G1 in plan view. According to the electro-optical device 10G of the third exemplary embodiment, as illustrated in FIG. 16, a retention capacitor D10 can be formed in a region where the electrode layer A6 and the gate electrode layer G1 overlap each other in plan view, and the retention capacitor D10 can be used as a pixel capacitor.

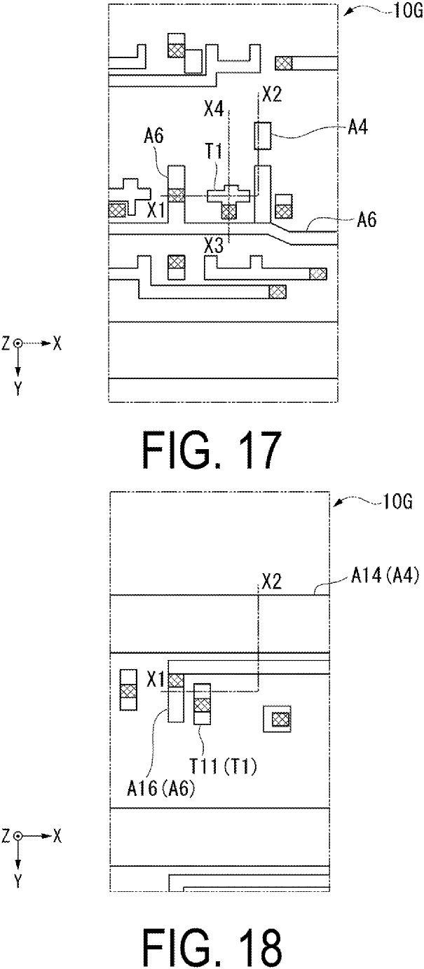

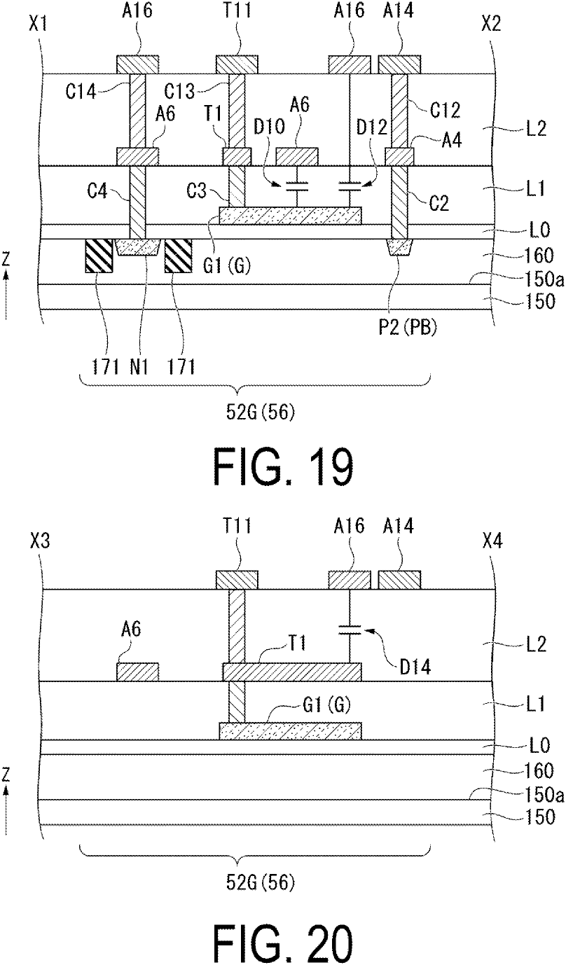

Each of FIGS. 17 to 20 is a schematic diagram illustrating a configuration of a modified example of the pixel circuit of the pixel 11G of the electro-optical device 10G of the third exemplary embodiment. FIG. 17 is a schematic diagram illustrating a layout in plan view at the front surface of the interlayer insulating layer L1 at the pixel circuit of the pixel 11G of the modified example of the third exemplary embodiment. A layout in plan view at the front surface of the gate insulation layer L0 at the pixel circuit of the pixel 11G of the modified example of the third exemplary embodiment is similar to that of the third exemplary embodiment. FIG. 18 is a schematic diagram illustrating a layout in plan view at the front surface of the interlayer insulating layer L2 at the pixel circuit of the pixel 11G of the modified example of the third exemplary embodiment. FIG. 19 is a diagram illustrating a configuration of the pixel circuit formed with the layout illustrated in FIGS. 14, 17, and 18, and is a cross-sectional view when viewed from a line X1-X2 illustrated in FIGS. 17 and 18. FIG. 20 is a diagram illustrating the configuration of the pixel circuit formed with the layout illustrated in FIGS. 14, 17, and 18, and is a cross-sectional view when viewed from a line X3-X4 illustrated in FIG. 17. In FIGS. 19 and 20, a configuration of an upper layer than the electrode layer A14, that is, a configuration of a front in the Z direction is omitted, but the electrode layer A14 is electrically coupled to the electrode layer A100 of the anode AN of the light-emitting element 54G.

In the pixel circuit of the pixel 11G of the electro-optical device 10G of the modified example of the third exemplary embodiment, as illustrated in FIGS. 17 to 19, for example, the electrode layers A6 and A16 are provided between the relay layer T1 and the electrode layers A4 and A14 in plan view. As described above, each of the relay layer T1 and the electrode layers A4 and A6 is provided at the front surface of the interlayer insulating layer L1. In addition, each of the electrode layers A14 and A16 is provided at the front surface of the interlayer insulating layer L2. Further, the gate electrode layer G1 overlaps the relay layer T1 and the gate electrode layers A6 and A16 in plan view. With such a layout, the retention capacitor D10 is formed between the gate electrode layer A6 and the gate electrode layer G1. Further, a retention capacitor D12 is formed between the layer A16 and the gate electrode layer G1.

As illustrated in FIGS. 17, 18, and 20, the electrode layer A16 is provided between the relay layer T11 and the electrode layer A14 in plan view, for example. In this extraction region, in addition to the gate electrode layer G1 at the front surface of the interlayer insulating layer L1, the relay layer T1 at the front surface of the interlayer insulating layer L2 extends to a position overlapping the gate electrode layer A16 in plan view. In such a layout, a retention capacitor D14 is formed between the electrode layer A16 and the relay layer T1 electrically equivalent to the gate electrode layer G1.

According to the electro-optical device 10G of the modified example of the third exemplary embodiment described above, as in the electro-optical device 10G of the third exemplary embodiment, the retention capacitors D10, D12, and D14 can be formed in a region where the electrode layers A6 and A16 and the gate electrode layer G1 overlap each other in plan view, to use the retention capacitors D10, D12, and D14 as pixel capacitors.

Although the preferred exemplary embodiments of the present disclosure have been described in detail above, the present disclosure is not limited to the specific exemplary embodiments, and various modifications and changes can be made within the scope of the gist of the present disclosure described in the claims. In addition, the components of the plurality of exemplary embodiments can be appropriately combined. For each of the above-described exemplary embodiments, the remarkable operational effects have been described. However, even when not described in detail, operational effects of other exemplary embodiments to which the configuration included in an own light source device is applicable can be obtained.

For example, the relative layouts of the electrode layers, the relay layers, and the gate electrode layers described with reference to the figures for the pixel circuits of the pixels of the electro-optical devices of the first to third exemplary embodiments are examples included in the present disclosure. The layout can be changed as appropriate within the scope of the claims described later, For example, as described in the modified example of the third exemplary embodiment, the relative layout of the electrode layer, the relay layer, and the gate electrode layer is freely designed by the combination of the positions in the Z direction at which the electrode layer, the relay layer, and the gate electrode layer are respectively formed, that is, the selection of the insulating layers forming each of the electrode layer, the relay layer, and the gate electrode layer, and the respective shapes of the electrode layer, the relay layer, and the gate electrode layer in plan view, and the types and number of layouts are not particularly limited.

In addition, although the head-mounted display has been described as the image display device including the electro-optical device according to the present disclosure, the image display device according to the present disclosure is not limited to the head-mounted display and may be, for example, a projector, an electronic view finder (EVF), a portable information terminal, a tablet device, or a wristwatch.

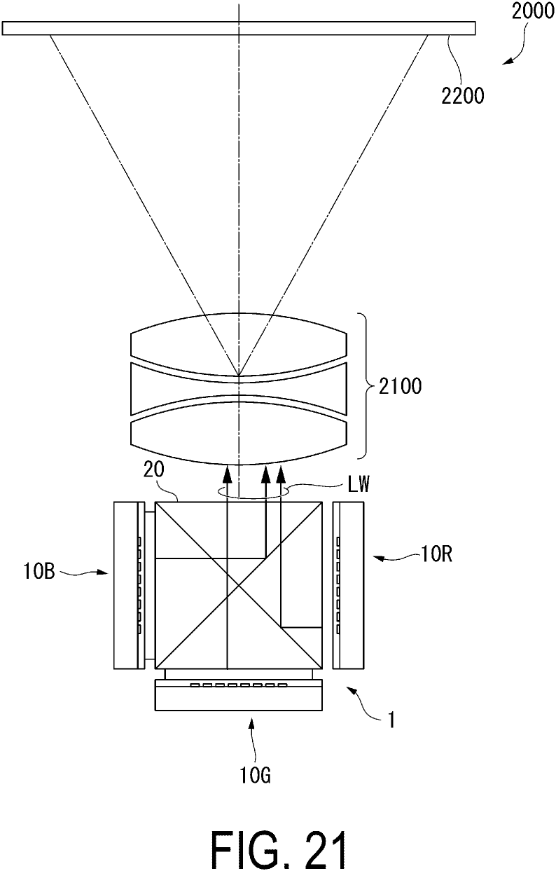

FIG. 21 is a schematic diagram illustrating a configuration of a projector 2000 including the electro-optical devices 10G, 10B, and 10R described above. For example, as illustrated in FIG. 21, the projector 2000 includes the optical device 1 described above, and a projection optical system (optical system) 2100 that expands and projects the synthesized image light LW emitted from the optical device 1 onto a screen 2200. According to the projector 2000, it is possible to optimize white balance of the synthesized image light LW projected onto the screen 2200, and to reduce power consumption of each of the electro-optical devices 10G and 10B as compared with the electro-optical device 10R.

An electro-optical device according to an aspect of the present disclosure may have the following configuration.
An electro-optical device according to one aspect of the present disclosure includes a light-emitting element including a first electrode, a light-emitting layer, and a second electrode, a driving transistor provided corresponding to the light-emitting element, a relay electrode electrically connected to a gate electrode of the driving transistor and provided at a layer between the gate electrode and the first electrode of the light-emitting element, a power supply line provided at the same layer as that of the relay electrode, extending in a first direction in plan view, and electrically connected to the first electrode of the light-emitting element, and a conductive member provided between the relay electrode and the power supply line in plan view and supplied with a constant potential.
In the electro-optical device according to [1] described above, a diffusion region containing an impurity may be included at a semiconductor substrate, and the conductive member may be electrically connected to the diffusion region.
In the electro-optical device according to [2] described above, the relay electrode may be surrounded by the conductive member in plan view.
In the electro-optical device according to [3] described above, the relay electrode may be provided adjacent to the conductive member with an insulating layer interposed between the relay electrode and the conductive member in plan view.
In the electro-optical device according to [1] or [2] described above, at least a part of the conductive member may overlap the gate electrode in plan view.
In the electro-optical device according to any one of [1] to [5] described above, the light-emitting element may be an organic light-emitting diode.
An image display device according to one aspect of the present disclosure includes the electro-optical device according to any one of [1] to [6] described above, and an optical system configured to display image light emitted from the electro-optical device.

What is claimed is:

1. An electro-optical device, comprising:
a light-emitting element including a first electrode, a light-emitting layer, and a second electrode;
a driving transistor provided corresponding to the light-emitting element;
a relay electrode electrically connected to a gate electrode of the driving transistor and provided at a layer between the gate electrode and the first electrode of the light-emitting element;
a power supply line provided at the same layer as that of the relay electrode, extending in a first direction in plan view, and electrically connected to the first electrode of the light-emitting element; and
a conductive member provided between the relay electrode and the power supply line in plan view and supplied with a constant potential.

2. The electro-optical device according to claim 1, further comprising:
a diffusion region containing an impurity at a semiconductor substrate, wherein
the conductive member is electrically connected to the diffusion region.

3. The electro-optical device according to claim 2, wherein
the relay electrode is surrounded by the conductive member in plan view.

4. The electro-optical device according to claim 3, wherein
the relay electrode is provided adjacent to the conductive member with an insulating layer interposed between the relay electrode and the conductive member in plan view.

5. The electro-optical device according to claim 1, wherein
at least a part of the conductive member overlaps the gate electrode in plan view.

6. The electro-optical device according to claim 1, wherein
the light-emitting element is an organic light-emitting diode.

7. An image display device, comprising:
the electro-optical device according to claim 1; and
an optical system configured to display image light emitted from the electro-optical device.
